(19) United States
(12) Patent Application Publication
(10) Pub. No.: US 2005/0239297 A1
(43) Pub. Date: Oct. 27, 2005

(54) Growth of high-k dielectrics by atomic layer deposition

(76) Inventors: Yoshihide Senzaki, Aptos, CA (US); Sang-In Lee, Cupertino, CA (US); Sattar Al-Lami, Santa Cruz, CA (US)

Correspondence Address: DORSEY & WHITNEY LLP, 555 CALIFORNIA STREET, SUITE 1000, SUITE 1000, SAN FRANCISCO, CA, 94104, US

(21) Appl. No.: 10/956,232

(22) Filed: Sep. 30, 2004

Related U.S. Application Data
(60) Provisional application No. 60/507,875, filed on Sep. 30, 2003.

(51) Int. Cl. H01L 21/44

(52) U.S. Cl. 438/785; 438/790

(57) ABSTRACT

In general, the present invention provides a method of depositing high-k dielectric films or layers, such as but not limited to high-k gate dielectric films. In one embodiment, atomic layer deposition (ALD) cycles are carried out where ozone is selectively conveyed to a chamber in separate cycles to form a metal oxide layer on the surface of a substrate where the metal oxide layer has an interfacial oxide layer of minimal thickness.

### CROSS REFERENCE TO RELATED APPLICATIONS

This application claims the benefit of and priority to U.S. Provisional Patent application Ser. No. 60/507,875 filed on Sep. 30, 2003, entitled Two Step Sequential Growth of High-k Gate Dielectrics by Atomic Layer Deposition, the entire disclosure of which is hereby incorporated by reference. This application is related to Patent Cooperation Treaty Patent application no. PCT/JUS03/22712, entitled Atomic Layer Deposition of High k Dielectric Films, the entire disclosure of which is hereby incorporated by reference.

### FIELD OF THE INVENTION

This invention relates generally to atomic layer deposition methods and systems. More specifically, the invention relates to a method of forming high dielectric constant (high-k) dielectric films or layers by atomic layer deposition.

### BACKGROUND OF THE INVENTION

Semiconductor devices of future generation require thin dielectric films for metal oxide silicon (MOS) transistor gates, and capacitor dielectrics. As oxide films are scaled down, the tunneling leakage current becomes significant and limits the useful range for SiO₂ gate oxides to about 1.8 nm or more.

High dielectric constant (“high-k”) metal oxides have been considered as possible alternative materials to silicon oxide (silicon dioxide has a dielectric constant k of about 3.9) to provide gate dielectrics with high capacitance but without compromising the leakage current. Metal oxides such as hafnium oxide (HfO₂) having a dielectric constant of about 20, zirconium oxide (ZrO₂) having a dielectric constant of about 20, and hafnium (Hf) and zirconium (Zr) silicates have been reported. However, prior art fabrication techniques such as chemical vapor deposition (CVD) are increasingly unable to meet the requirements of forming these advanced thin films. While CVD processes can be tailored to provide conformal films with improved step coverage, CVD processes often require high processing temperatures, result in incorporation of high impurity concentrations, and have poor precursor or reactant utilization efficiency. For instance, one of the obstacles in fabricating high-k gate dielectrics is the formation of an interfacial silicon oxide layer during CVD processing. Interfacial oxide growth problems for gate and capacitor dielectric applications have been widely reported in the industry. This problem has become one of the major hurdles for implementing high-k materials in advanced device fabrication. Another obstacle is the limitation of prior art CVD processes in depositing ultra thin (typically 10 Å or less) films for high-k gate dielectrics on a silicon substrate.

Atomic layer deposition (ALD) is an alternative to traditional CVD processes to deposit very thin films. ALD has several advantages over traditional CVD techniques. ALD can be performed at comparatively lower temperatures which is compatible with the industry's trend toward lower temperatures, has high precursor utilization efficiency, and can produce conformal thin film layers. More advantageously, ALD can control film thickness on an atomic scale.

A bare silicon surface tends to self oxidize in the air and form a thin film referred to as a native oxide. The silicon oxide surface is referred to as a hydrophilic surface. The native oxide is a poor quality insulator in terms of leakage and other electrical properties, and therefore, the native oxide is ordinarily removed. To remove the oxide, HF is typically applied across the film, and this process leaves the silicon surface terminated with hydrogen atoms and forms what is referred to as a hydrophobic surface.

In the conventional atomic layer deposition (ALD) processing of high-k gate oxide deposition, growth inhibition on silicon substrates pretreated or cleaned with Hf (hydrogen terminated, namely, hydrophobic) is reported. This leads to non-continuous “island” formation at a nucleation stage of the metal oxide film growth and degrades the silicon/oxide interface properties of the gate stack.

These interfacial oxides are not desired and need to be suppressed in order to achieve low EOT values. Further, prior to the metal oxide deposition, silicon substrates are commonly oxidized to form a bottom oxide layer having a thickness of about 8-10 Å by rapid thermal oxidation in order to form a hydrophilic surface after removal of the native oxide by HF etching. However, this intentional growth of an interfacial oxide undesirably increases the equivalent oxide thickness (EOT) of the gate oxide.

Accordingly further developments are needed. It would be particularly beneficial to develop processes which address this problem and preferably that can be carried out without change in the deposition reaction configuration or additional process steps.

### BRIEF SUMMARY OF THE INVENTION

In general, the present invention provides a method of depositing high-k dielectric films or layers, such as but not limited to high-k gate dielectric films. In one embodiment, atomic layer deposition (ALD) cycles are carried out where ozone is selectively conveyed to a chamber in separate cycles to form a metal oxide layer on the surface of a substrate where the metal oxide layer has an interfacial oxide layer of minimal thickness.

In one aspect of the present invention, a method of depositing a gate dielectric on a substrate using atomic layer deposition is provided carried out by the steps of: independently pulsing one or more chemical precursors, such as metal containing precursors, and ozone to a chamber, said ozone being pulsed at a high concentration and then reducing the concentration of ozone after one or more oxide layers have been formed on the substrate.

In another aspect of the present invention, one or more substrates are placed in an ALD reactor or chamber. In a first cycle, one or more chemical precursors are pulsed or conveyed to the chamber, and ozone (O₃) at a first flow rate and first pulse duration is pulsed to the chamber either before or after the precursor pulse to form one or more layers of metal oxide on the substrate. In a second cycle, after one or more layers of metal oxide are formed on the substrate, the chemical precursor is pulsed to the chamber, and ozone is pulsed at a second flow rate and second pulse duration to the chamber. The first ozone flow rate and first pulse duration are selected such that the concentration of ozone in the first cycle is greater than the concentration of ozone in the second cycle. The second cycle may be repeated any number of times (N) until a layer of desired thickness is formed. Without being bound by any particular theory, this reduction in ozone concentration appears to suppresses interfacial oxide growth at the interface of the substrate and the metal oxide layer.

### BRIEF DESCRIPTION OF THE DRAWINGS

Advantages and embodiments of the present invention will become apparent upon reading the following detailed description and upon reference to the following figures, in which:

FIGS. 1A and 1B are flowcharts illustrating two embodiments of the method of the present invention;

FIG. 2 is a graph showing oxide thickness of films formed at different ozone (O₃) conditions according to various embodiments of the present invention;

FIG. 3 is a capacitance-voltage (CV) plot for HfO₂ layers deposited at different ozone process conditions of the present invention;

FIG. 4 is a graph illustrating leakage current density versus volts for HfO₂ layers deposited according to various embodiments of the present invention;

FIG. 5 is a graph of surface state sites (Nss) for HfO₂ layers formed according to various ozone conditions of the present invention;

FIGS. 6A-6D are SEM photographs showing nucleation of H₂O based ZrO₂ and HfO₂ films as reported in the prior art; and

FIG. 7 is a CV plots for Al₂O₃ layers formed according to one embodiment of the present invention, and illustrates the effect of ozone concentration on electrical properties.

### DETAILED DESCRIPTION OF THE INVENTION

In general, the present invention provides atomic layer deposition (ALD) cycles carried out where ozone is selectively conveyed to a chamber in separate cycles to form substantially continuous oxide layer on the surface of a substrate where the oxide layer has an interfacial oxide layer of minimal thickness. In one embodiment, the interfacial oxide layer has a thickness of one monolayer. Preferably the interfacial oxide layer does not exceed a monolayer.

In one aspect of the present invention, a method of depositing a gate dielectric on a substrate using atomic layer deposition is provided by the steps of: independently pulsing one or more chemical precursors and ozone to a chamber, said ozone being pulsed at a high concentration and then reducing the concentration of ozone after one or more metal oxide layers have been formed on the substrate.

In another aspect of the present invention, one or more substrates are placed in an ALD reactor or chamber. In a first cycle, a metal containing precursor is pulsed or conveyed to the chamber and ozone (O₃) at a first concentration is pulsed to the chamber either before or after the precursor pulse to form one or more layers of metal oxide on the substrate. In a second cycle, after one or more layers of metal oxide are formed on the substrate, the metal containing precursor is pulsed to the chamber and ozone is pulsed at a second concentration to the chamber, the second concentration being lower than the first flow rate. Generally, the first cycle will be carried out from 1 to 10 times, and the second cycle will be carried out from 1 to N times, where N is determined according to the desired thickness of the films. Typically the second cycle will be repeated more than the first cycle.

The concentration of ozone in the first and second cycles may be varied or controlled in a variety of ways. In one embodiment, the concentration of ozone is increased or reduced by varying the flow rate of ozone conveyed to the chamber. In another embodiment, the concentration of ozone is controlled in the separate cycles by increasing or decreasing the pulse duration, i.e. the period of time ozone is pulsed to the chamber. In yet another embodiment, the concentration of ozone in the separate cycles is varied by a combination of both flow rate and pulse duration of ozone.

The concentration of ozone in the first cycle is greater than the concentration of ozone in the second cycle. In one example, the concentration of ozone in the first cycle is in the range of 1.1 to 4 times the concentration of ozone in the second cycle. More usually, the concentration of ozone in the first cycle is generally, but not limited to, 1.25 to 3 times the concentration of ozone in the second cycle. In one exemplary embodiment, the flow rate of ozone in the first cycle is approximately 250 g/m³ for a pulse duration of two seconds, while the flow rate of ozone during the second cycle is approximately 180 g/m³ for two seconds. In another example, the flow rate of ozone during the first cycle is ramped up, such as from a value of approximately 180 g/m³ to 240 g/m³ during the duration of the first cycle, and the flow rate of ozone during the second cycle is approximately 180 g/m³. In yet another example, the flow rate of ozone during the first cycle is approximately 180 g/m³ but the pulse duration is four seconds, while the flow rate of ozone during the second cycle is approximately 180 g/m³ for a pulse duration of two seconds. In still a further example, the flow rate of ozone during the first cycle is approximately 360 g/m³ for a pulse duration of two seconds and the flow rate of ozone in the second cycle is approximately 180 g/m³ for a pulse duration of two seconds. When longer pulse times are used to increase the concentration of ozone in the first cycle, the ozone pulse duration in the first cycle is typically, but not limited to, 1.25 to 5 times longer than the ozone pulse duration in the second cycle. The foregoing examples are provided for illustration purposes only and are not meant to limit the invention in any way. As will be apparent to those of ordinary skill in the art many variations of flow rate and pulse duration are possible to achieve a higher concentration of ozone in the first cycle than in the second cycle according to the teaching of the present invention. Further, it should be understood that the absolute values given for the different flow rates and pulse durations, as well as the ratios of these values, may vary dependent upon the type and size of ALD equipment utilized, including the process chamber and gas delivery system configurations, among others.

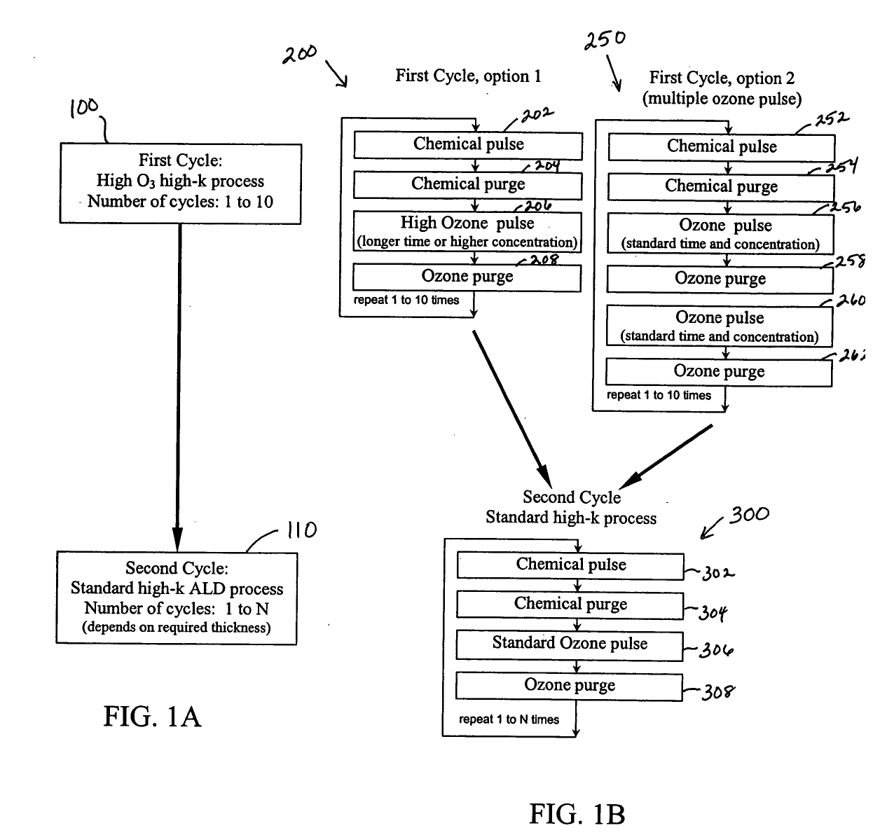

Referring to FIGS. 1A and 1B, embodiments of the method of the present invention are shown. The exemplary embodiments are shown for illustration purposes only and are not meant to limit the invention in any way. Generally, as shown in simplified form in FIG. 1A, the first ALD cycle is carried out at step 100 where ozone at a first (high) concentration is pulsed. This first cycle is repeated from 1 to 10 times. Next, at step 110, the second ALD cycle is carried out where ozone at a second (reduced) concentration is pulsed. This second cycle is repeated from 1 to N times, N being determined by the desired thickness of the film to be formed.

FIG. 1B illustrates two alternative embodiments of the method of the present invention. The first cycle, option 1, higher ozone concentration is achieved by either longer pulse duration of ozone or greater ozone flow rate. More specifically, the first cycle, option 1, is carried out at step 200 and comprises pulsing one or more chemical precursors at step 202, followed by purging the chemical precursor at step 204. Next ozone is pulsed at a specific duration and/or flow rate that achieves a higher ozone concentration or higher ozone exposure than will be used in the second cycle (step 300). Finally, ozone is purged from the chamber at step 206. This first cycle may be repeated from 1 to 10 times.

Alternatively, the first cycle may be carried out as shown in option 2 at step 250. In this embodiment increased ozone concentration is achieved by sequentially repeating the ozone pulse and purge steps. More specifically, the first cycle, option 2, is carried out at step 250 and comprises pulsing one or more chemical precursors at step 252, followed by purging the chemical precursor at step 254. Next, ozone is pulsed to the chamber at step 256 at the same duration and/or flow rate as that used in the second cycle (step 300) and then purged at step 258. Increased exposure to ozone is achieved by sequentially repeating the ozone pulse/purge step by pulsing zone again at step 260 and purging ozone at step 262. This first cycle may be repeated from 1 to 10 times. In one example the first cycle was repeated six times.

After completing the first ALD cycle (either steps 200 or 250), the second ALD cycle is carried out at step 300. In the second cycle reduced ozone exposure is used. Generally the second cycle is carried out at step 300 and comprises pulsing one or more chemical precursors at step 302, followed by purging the chemical precursor at step 304. Next, ozone is pulsed at step 306 at a concentration lower than that used in the first cycle. Finally, ozone is purged at step 308. This second cycle may be repeated from 1 to N times, N being determined by the desired thickness of the film. The number of repetitions of the second cycle is typically greater than the number of repetitions of the first cycle.

When forming high performance gate insulators or capacitor insulators, high-k (meaning a dielectric constant of about 10 or more) dielectric materials with EOT less than about 12 Angstroms (i.e., 1.2 nm) are preferred. Customarily, to form the dielectric, a thin hydrophilic SiO₂ interfacial layer of less than 5 Angstroms (i.e., 0.5 nm) is formed on a hydrophobic Si surface that has be cleaned or conditioned with HF. Then, a dielectric material is grown on the thin SiO₂ interfacial layer using ALD.

The method of the present invention may be carried out in any suitable chamber configured for ALD. For example, in one embodiment a process chamber is configured in such a manner as to practice the inventive method on a single substrate. Alternatively, the process chamber is configured in such a manner as to practice the inventive method on a plurality of substrates, typically numbering between 1 and 200 substrates. In one example a batch process chamber contains between 1 and 200 substrates when the substrates are silicon wafers with a diameter of 200 mm. More typically, a process chamber contains between 1 and 150 substrates when the substrates are silicon wafers with a diameter of 2000 mm. If the substrates are silicon wafers with a diameter of 300 mm, it would be more typical for the process chamber to contain between 1 and 100 substrates. A “mini-batch” reactor may also be employed wherein a batch of substrates numbering between 1 and 50 are housed in a process chamber. In this case the substrates are typically silicon wafers with diameters of either 200 mm and 300 mm. Alternatively the mini-batch process chamber is configured to process between 1 and 25 substrates. One example of a mini-batch system is described in PCT patent application serial no. PCT/US03/21575 entitled Thermal Processing System and Configurable Vertical Chamber, the entire disclosure of which is incorporated by reference herein. While a number of examples are described it should be understood that the present invention may be carried out in a variety of ALD systems.

In one embodiment of the present invention, the chemical precursor is a metal containing precursor comprising at least one deposition metal, having the formula:
M(L)x
where M is a metal selected from the group consisting of Ti, Zr, Hf; Ta, W, Mo, Ni, Si, Cr, Y, La, C, Nb, Zn, Fe, Cu, Al, Sn, Ce, Pr, Sm, Eu, Tb, Dy, Ho, Er, Tm, Yb, Lu, Ga, In, Ru, Mn, Sr, Ba, Ca, V, Co, Os, Rh, Ir, Pd, Pt, Bi, Sn, Pb, Tl, Ge or mixtures thereof; where L is a ligand selected from the group consisting of amine, amides, amidinates, alkoxides, halogens, hydrides, alkyls, azides, nitrates, nitrites, cyclopentadienyls, carbonyl, carboxylates, diketonates, alkenes, alkynes, or a substituted analogs thereof, and combinations thereof; and where x is an integer less than or equal to the valence number for M.

In one preferred embodiment the metal containing precursor is selected where M is hafnium. The hafnium precursor may comprise any one or combination of hafnium dialkyl amides, hafnium alkoxides, hafnium dieketonates, hafnium chloride (HfCl4), tetrakis(ethylmethylamino) hafnium (TEMA-Hf), and the like. In another embodiment, the metal containing precursor is selected where M is aluminum (Al). The aluminum containing precursor may comprise any one or combination of trimethyl aluminum, diethyl aluminum hydride, aluminum alkoxide, aluminum dialkyamide, and the like.

In one example the ALD process is carried out at a process temperature in the range of approximately 25 to 800° C., more usually in the range of approximately 50 to 600° C., and most usually in the range of approximately 100 to 500° C. The pressure in the process chamber is in the range of approximately 0.001 mTorr to 600 Torr, more usually in the range of approximately 0.01 mTorr to 100 Torr, and most usually in the range of approximately 0.1 mTorr to 10 Torr.

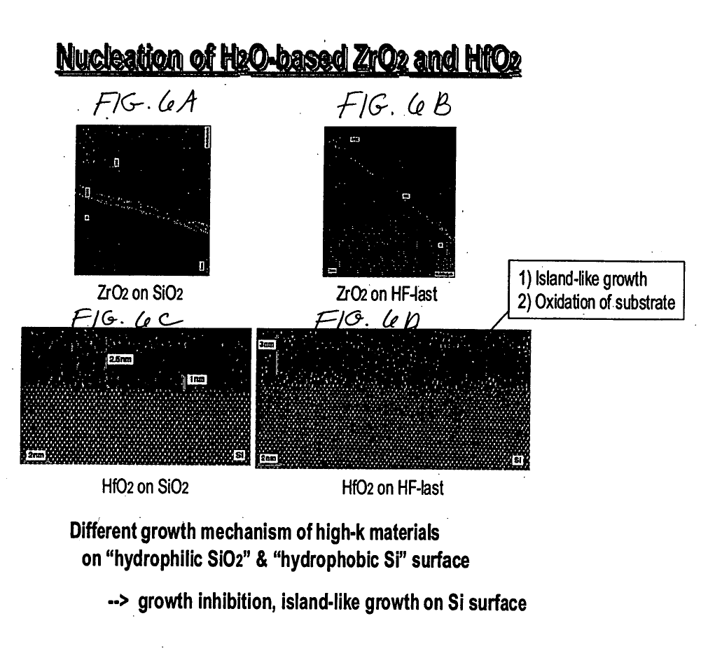

In the case of H₂O-based ALD of metal oxide, an incubation period prior to the film growth was noted. Using highly reactive O₃ as a reactant gas, the metal oxide nucleation is facilitated. In the ALD of high-k metal oxides, no induction period was observed on hydrophobic silicon substrate surface when sufficient O₃ flow was pulsed after the precursor pulse/purge steps. It is believed that ozone helps to nucleate metal oxide, and thus suppresses discontinuous island growth. When carrying out the method of the present invention, two separate ALD cycles are provide, and without being bound by any particular theory it is believed that in the first cycle the high O₃ flow rate facilitates metal oxide nucleation on hydrogen terminated silicon substrates. FIGS. 6A to 6D are SEM photographs showing different growth mechanisms on both “hydrophilic SiO₂” and “hydrophobic Si” surfaces. Growth inhibition, forming undesirable island like growth is also shown.

After a one or more metal oxide layers are grown on the entire silicon substrate, the second ALD cycle is initiated wherein the ozone exposure is reduced. It is believed that this promotes suppression of the interfacial oxide growth at the interface of the substrate and the metal oxide layer.

High reactivity of atomic oxygen generated from ozone facilitates nucleation of metal oxide on H terminated silicon substrate. The initial high ozone concentration pulse and subsequent low ozone concentration pulse in combination of a constant chemical precursor pulse provides high-k gate oxides with good interfacial properties in metal-oxide-semiconductor (MOS) devices.

In one embodiment, the ALD process is carried out using ozone and a metal organic as precursors, at a temperature in the range of 25° C. to 500° C., and more usually at a temperature in the range of 50° C. to 450° C. Examples of metal organic precursors include hafnium (Hf) amide or Hf(O-t-Bu)₄ where O-t-Bu is a tertiary butoxy anion to form a hafnium oxide (HfO₂) layer.

### EXPERIMENTAL

A number of experiments were carried out according to the method of the present invention. While exemplary embodiments are described, the particular experiments are not meant to limit the invention, but are presented for illustration only. HfO₂ films were deposited using TEMAH and ozone under different process conditions. These conditions included ozone flow rate changes and include—: flow rate, pulse duration and the flow sequence with TEMAH during the first step of five deposition cycles. The deposition conditions of the first ALD cycle and the process are depicted in Table 1 below.

TABLE 1
Deposition conditions at 300° C. and varying O₃ pulse time (sec)

| W # | # Cycle: O₃ | Process Conditions |
|---|---|---|
| 2 & 3 | 05: High conc. | 05 cycles 240 g/m3 O3 - Hf: 2.5/Purge: 4/O3: 2/Purge: 2 |
| | 55: baseline | 55 cycles 180 g/m3 O3 - Hf: 2.5/Purge: 4/O3: 2/Purge: 2 |
| 4 & 5 | 05: Long pulse | 05 cycles 180 g/m3 O3 - Hf: 2.5/Purge: 4/O3: 4/Purge: 3 |
| | 55: baseline | 55 cycles 180 g/m3 O3 - Hf: 2.5/Purge: 4/O3: 2/Purge: 3 |
| 6 & 7 | 05: Short Pulse | 05 cycles 180 g/m3 O3 - Hf: 2.5/Purge: 4/O3: 2/Purge: 3/O3: |
| | 55: baseline | 2/Purge: 3 55 cycles 180 g/m3 O3 - Hf: 2.5/Purge: 4/O3: 2/ |
| | | Purge: 3 |
| 8 & 9 | 60: Reverse | 60 cycles 180 g/m3 O3 - O3: 2/Purge: 3/Hf: 2.5/Purge: 4 |
| | Pulse | |
| 12 & 13 | 60: baseline | 60 cycles 180 g/m3 O3 - Hf: 2.5/Pure: 4/O3: 2/Pure: 3 |

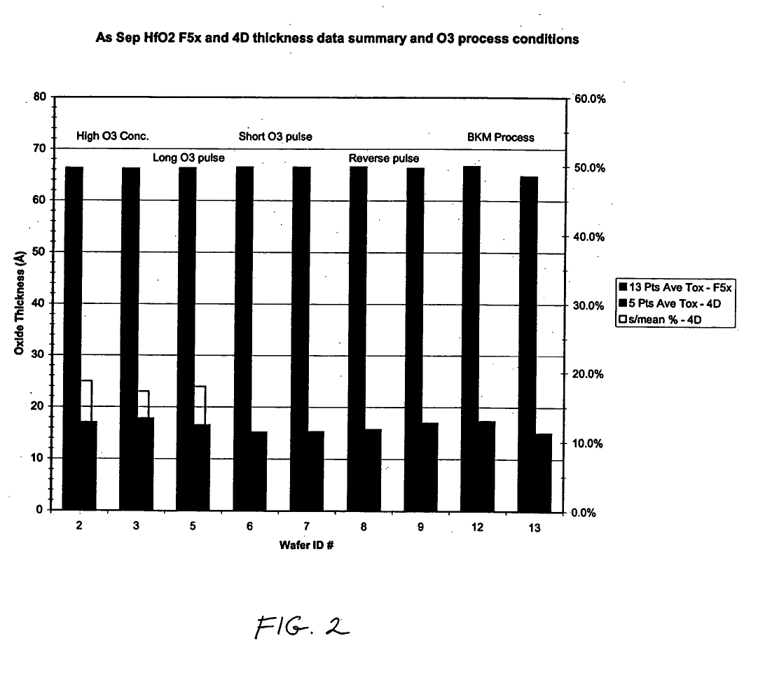

Oxide thickness measurements by ellipsometer (F5X) and mercury probe (4D) are shown in Table 2 and FIG. 2 and indicate that high ozone concentration do not show significant thickness increase with high ozone concentration

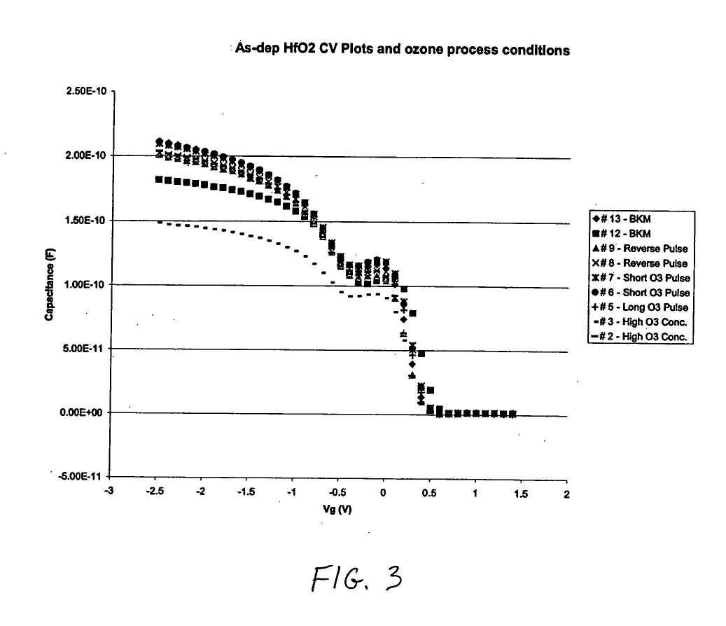

CV plots are shown in FIG. 3 and illustrate that the high O₃ concentration may improve the flat band voltage by shifting the CV plot to the left, reducing its value. FIG. 3 also shows that the Cmin/Cmax ratio is extremely low for all conditions tested suggesting low concentration of minority carriers in the silicon. This seems to be unique to HfO₂ film. In comparison, the CV base line data from Al₂O₃ film show higher Cmin/Cmax or similar p-type silicon wafers.

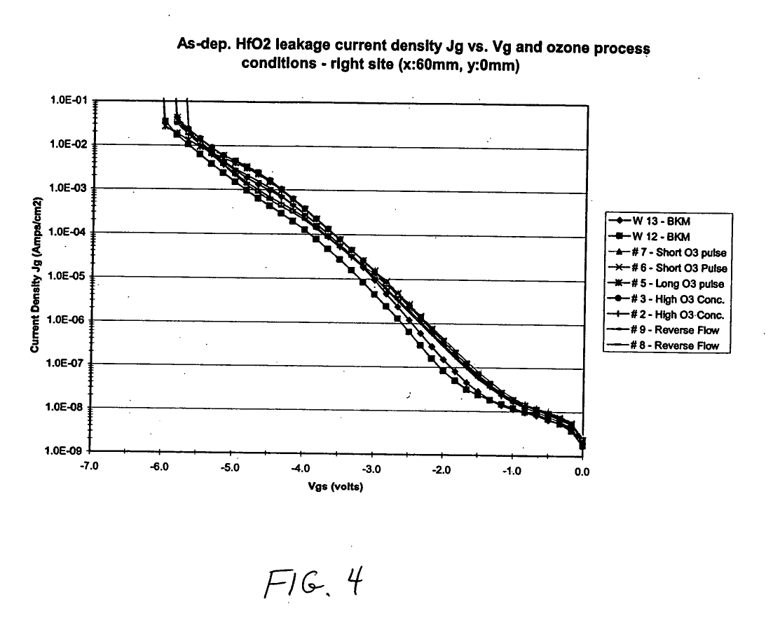

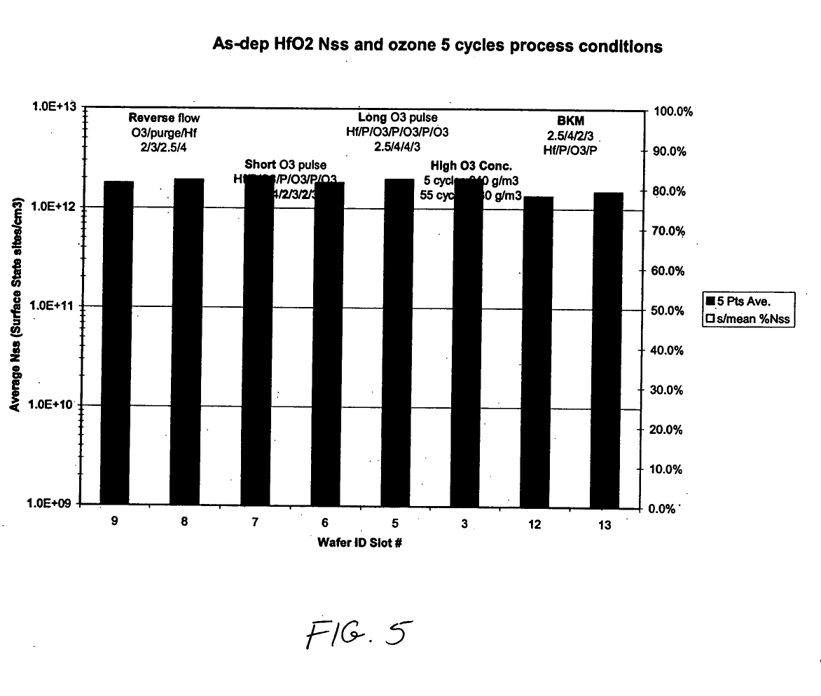

Regarding current leakage density at −1.0 V (Jg) and the surface states density (Nss), Table 2, FIG. 4 and FIG. 5 show that, within the mercury probe sensitivity, no significant change in either Jg and or Nss were measured as a result of the variation in ozone flow rate in the two ALD cycles according to the present invention.

TABLE 2
HfO2 Film thickness (Å) & leakage current density Jg (A/Cm2)

| | | 4D (EOT) | | |
|---|---|---|---|---|
| | | 5 Pts Ave/SD | Ellipometer | |
| W # | O3 Cycle | % mean | 13 Pts Ave | Jg (A/Cm2) × E-8 |
| 2 | High Conc. | 17.03/18.7% | 66.3 | 1.70 |
| 3 | High Conc. | 17.82/17.2% | 66.2 | 1.72 |
| 5 | Long Pulse | 16.52/17.9% | 66.3 | 2.70 |
| 6 | Short Pulse | 15.21/02.3% | 66.5 | 1.80 |
| 7 | Short Pulse | 15.29/02.1% | 66.5 | 1.87 |
| 8 | Reverse Pulse | 15.78/02.7% | 66.6 | 1.95 |
| 9 | Reverse Pulse | 17.04/16.1% | 66.3 | 1.83 |
| 12 | Baseline | 17.35/1.95% | 66.7 | 1.20 |
| 13 | Baseline | 15.07/01.1% | 64.8 | 1.13 |

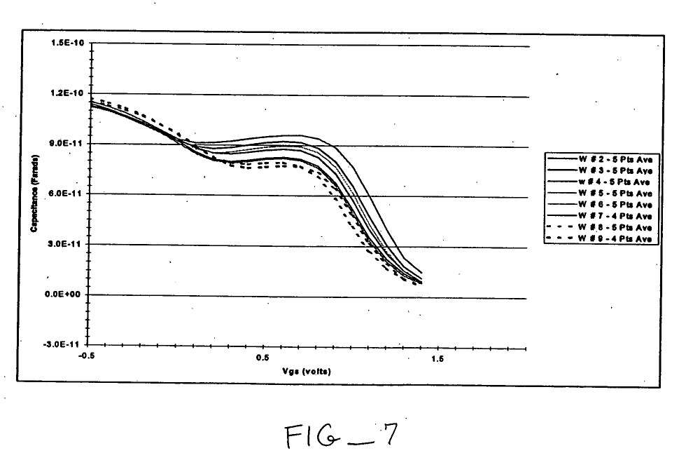

In another experiment Al₂O₃ films were deposited using TMA and ozone as precursors. The effect of O₃ concentration on the electrical properties of the resulting Al₂O₃ films is illustrated in FIG. 7. FIG. 7 shows that the CV plots have shifted to left towards a smaller flat band voltage indicating a reduction in the oxide charges as the O₃ concentration is increased.

Another variation of improving the electrical properties on high-k metal oxide is to insert additional ozone pulses in, for example, every 5 to 20 cycles as ALD high-k metal oxides; thus, metals oxides are annealed “in-situ” in ozone stepwise in the same chamber as the metal oxide films are grown by ALD.

Exemplary embodiments have been described with reference to specific configurations. The foregoing description of specific embodiments and examples of the invention have been presented for the purpose of illustration and description, and although the invention has been illustrated by certain of the preceding examples, it is not to be construed as being limited thereby.

1. A method of depositing a dielectric film on a substrate by atomic layer deposition, comprising the steps of:
pulsing ozone at a high concentration either before or after precursor/purge steps; and
reducing the ozone concentration after one or more metal oxide layers have been formed on the substrate.

2. A method of depositing a dielectric film on a substrate characterized in that atomic layer deposition (ALD) cycles are carried out where ozone is selectively conveyed to a chamber in separate ALD cycles to form an oxide layer on the surface of a substrate, and where the oxide layer has an interfacial oxide layer, and the thickness of the interfacial oxide layer is at least one monolayer.

3. A method of depositing a dielectric film on a substrate by atomic layer deposition, comprising the steps of:
in a first cycle, separately pulsing one or more chemical precursors and ozone to a chamber, where ozone is pulsed at a first flow rate and first pulse duration; and
in a second cycle, separately pulsing one or more chemical precursors and ozone to the chamber, where ozone is pulsed at a second flow rate and second pulse duration, and where the first flow rate and first pulse duration are selected such that the concentration of ozone in the first cycle is greater than the concentration of ozone in the second cycle.

4. The method of claim 3 wherein the concentration of ozone in the first cycle is approximately 1.25 to 3 times the concentration of ozone in the second cycle.

5. The method of claim 3 wherein the first pulse duration is approximately 1.25 to 5 times longer in duration than the second pulse duration.

6. The method of claim 3 wherein the first cycle further comprises: sequentially repeating the ozone pulse step.

7. The method of claim 3 wherein the method of carried out at a temperature in the range of 25° C. to 500° C.

8. The method of claim 3 wherein the one or more chemical precursor is a metal containing precursor.

9. The method of claim 8 wherein the metal containing precursor is of the formula:
M(L)x
where M is a metal selected from the group consisting of Ti, Zr, Hf, Ta, W, Mo, Ni, Si, Cr, Y, La, C, Nb, Zn, Fe, Cu, Al, Sn, Ce, Pr, Sm, Eu, Th, Dy, Ho, Er, Tm, Yb, Lu, Ga, In, Ru, Mn, Sr, Ba, Ca, V, Co, Os, Rh, Ir, Pd, Pt, Bi, Sn, Pb, Ti, Ge or mixtures thereof; where L is a ligand selected from the group consisting of amine, amides, amidinates, alkoxides, halogens, hydrides, alkyls, azides, nitrates, nitrites, cyclopentadienyls, carbonyl, carboxylates, diketonates, alkenes, alkynes, or a substituted analogs thereof, and combinations thereof; and where x is an integer less than or equal to the valence number for M.

10. The method of claim 9 wherein M is hafnium.

11. The method of claim 3 wherein the chemical precursor is comprised of any one or combination of hafnium dialkyl amides, hafnium alkoxides, hafnium dieketonates, hafnium chloride (HfC14), tetrakis(ethylmethylamino) hafnium (TEMA-Hf).

12. The method of claim 9 wherein M is aluminum.

13. The method of claim 3 wherein the chemical precursor is comprised of any one or combination of trimethyl aluminum, diethyl aluminum hydride, aluminum alkoxide, aluminum dialkyamide.

14. The method of claim 3 where the first flow rate and second flow rate are substantially equal, and the first pulse duration is at least twice the second pulse duration.

15. The method of claim 3 wherein the one or more chemical precursors is a metal organic compound.

16. The method of claim 15 wherein the metal organic precursor comprises any one or combination of: hafnium (Hf) amide or Hf(O-t-Bu)₄, where O-t-Bu is a tertiary butoxy anion.

17. The method of claim 3 wherein the method of carried out at a temperature in the range of 50° C. to 450° C.

18. The method of claim 9 wherein M is comprised of both hafnium and silicon.

19. The method of claim 3 wherein the one or more chemical precursors includes a hafnium precursor and a silicon precursor, and the hafnium precursor is comprised of any one or combination of hafnium dialkyl amides, hafnium alkoxides, hafnium dieketonates, hafnium chloride (HfC14), tetrakis(ethylmethylamino) hafnium (TEMA-Hf); and the silicon precursor is comprised of any one or combination of silicon dialkyl amides, silicon alkoxides, silicon chloride, tetrakis(ethylmethylamino) silicon (TEMA-Si), silane, dichlorosilane, tetramethyldisiloxane.

20. The method of claim 3 wherein the first flow rate of ozone is in the range of approximately 180 g/m³ to 360 g/m³.
